(19) United States
(12) Patent Application Publication
(10) Pub. No.: US 2026/0354248 A1
(43) Pub. Date: Nov. 5, 2026

(54) ELECTRONIC CHIP WITH UBM-TYPE METALLIZATION

(71) Applicant: Commissariat à l'Énergie Atomique et aux Énergies Alternatives, Paris (FR)

(72) Inventors: Clément Lobre, Grenoble Cedex 9 (FR); Eva Serres, Grenoble Cedex 9 (FR); Ludovic Dupre, Grenoble Cedex 9 (FR)

(73) Assignee: Commissariat à l'Énergie Atomique et aux Énergies Alternatives, Paris (FR)

(21) Appl. No.: 19/733,787

(22) Filed: Jul. 7, 2026

Related U.S. Application Data
(62) Division of application No. 18/477,544, filed on Sep. 28, 2023.

(30) Foreign Application Priority Data
Oct. 3, 2022 (FR) 2210096

(51) Int. Cl. H10W 72/90; H10W 72/00

(52) U.S. Cl. CPC H10W 72/90; H10W 72/019; H10W 72/01953; H10W 72/923; H10W 72/952; H10W 72/981

(57) ABSTRACT

An electronic chip including a substrate and, on the side of one face of the substrate, a metal pad intended to receive a soldering material, the pad including, in order from said face of the substrate, a first metal layer, an electrically conductive barrier layer, and a second metal layer, wherein an electrically insulating barrier layer is arranged on, and in contact with, the sidewall of the first metal layer over the entire periphery of the metal pad.

### CROSS REFERENCE TO RELATED APPLICATIONS

This application claims priority to French application number 2210096, filed Oct. 23, 2022. The contents of which is incorporated by reference in its entirety.

### TECHNICAL FIELD

The present description relates generally to the field of electronic chips and, more particularly, to the field of assembly and electrical connection of an electronic chip to an external electronic device.

### BACKGROUND ART

The assembly and connection of an electronic chip to a device external to the chip can be performed by soldering, i.e. by depositing a connection ball made of an electrically conductive soldering material at the interface between a metal contact on the chip and a corresponding metal contact on the external device. On the chip side, the metal contact generally comprises an Under Bump Metallization or UBM including several layers that provide good ohmicity of the contact, act as a barrier to metal diffusion into the contact, and provide a good adhesion of the connection ball to the contact.

There is a need to improve at least in part some aspects of electronic chips with UBM-type metallizations and their manufacturing methods.

### SUMMARY OF INVENTION

One embodiment provides an electronic chip including a substrate and, on the side of one face of the substrate, a metal pad intended to receive a soldering material, the pad including, in order from said face of the substrate, a first metal layer, an electrically conductive barrier layer, and a second metal layer, wherein an electrically insulating barrier layer is disposed on, and in contact with, the sidewall of the first metal layer over the entire periphery of the metal pad.

According to one embodiment, the electrically insulating barrier layer is arranged on, and in contact with, at least a part of the sidewall of the electrically conductive barrier layer.

According to one embodiment, the soldering material comprises indium.

According to one embodiment, the first and second metal layers are made of gold.

According to one embodiment, the electrically insulating barrier layer is made of zinc sulphide, or silicon dioxide.

According to one embodiment, the substrate is made of an alloy of cadmium, mercury, and telluride.

Another embodiment provides a method for manufacturing an electronic chip, including the following successive steps:
a) on a substrate, successively depositing a first metal layer, an electrically conductive barrier layer, and a second metal layer;
b) etching the first metal layer, the electrically conductive barrier layer, and the second metal layer so that a metal pad is defined by means of a single photolithography step; and
c) forming an electrically insulating barrier layer on, and in contact with, the sidewall of the first metal layer around the entire periphery of the metal pad.

According to one embodiment, the method includes, prior to step a), a step of depositing a passivation layer on the top face of the substrate, and wherein the electrically insulating barrier layer of step c) is formed by extending the etching of step b) into the passivation layer, and redepositing the etching material on the sidewalls of the metal pad.

According to one embodiment, step c) comprises a step of depositing an insulating material over the entire chip surface and a step of unidirectional etching to maintain said insulating material only on the sidewalls of the metal pad to form the electrically insulating barrier layer.

According to one embodiment, step c) comprises depositing an insulating material over the entire surface of the electronic chip, after depositing a sacrificial layer on the top face of the metal pad, then removing the sacrificial layer to expose the top face of the metal pad, and maintaining the insulating material on the sidewalls of the metal pad so as to form the barrier layer.

According to one embodiment, step c) comprises a step of depositing an insulating material over the entire surface of the electronic chip so as the metal pad and the top face of the substrate are covered, followed by a step of planarizing intended to uncover the top face of the metal pad.

According to one embodiment, step c) comprises a step of depositing an insulating material over the entire surface of the electronic chip, a step of depositing a sacrificial layer over the entire surface of the electronic chip, a step of plasma etching the entire surface of the electronic chip so that the top face of the insulating material opposite the metal pad is exposed, a step of ion etching the entire surface of the chip so that the top face of the metal pad is exposed, and finally a step of removing what remains of the sacrificial layer by wet etching.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a schematic, partial cross-sectional view of an example electronic chip with UBM-type metallization;

FIG. 2 is a schematic, partial cross-sectional view of an electronic chip with UBM-type according to one embodiment;

FIG. 3 illustrates a first example electronic chip of the type described in relation to FIG. 2;

FIG. 4 illustrates a second example electronic chip of the type described in relation to FIG. 2;

FIG. 5A and FIG. 5B illustrate successive steps in a method for forming a third example electronic chip of the type described in relation to FIG. 2;

FIG. 6A and FIG. 6B illustrate successive steps in a method for forming a fourth example electronic chip of the type described in relation to FIG. 2; and

FIG. 7A, FIG. 7B, and FIG. 7C illustrate successive steps in a method for forming a fifth example electronic chip of the type described in relation to FIG. 2.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, only forming an UBM-type metallization of an electronic chip has been detailed. Forming other elements of the chip, and in particular integrated circuits and electronic components present in the chip, has not been described in detail.

Indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

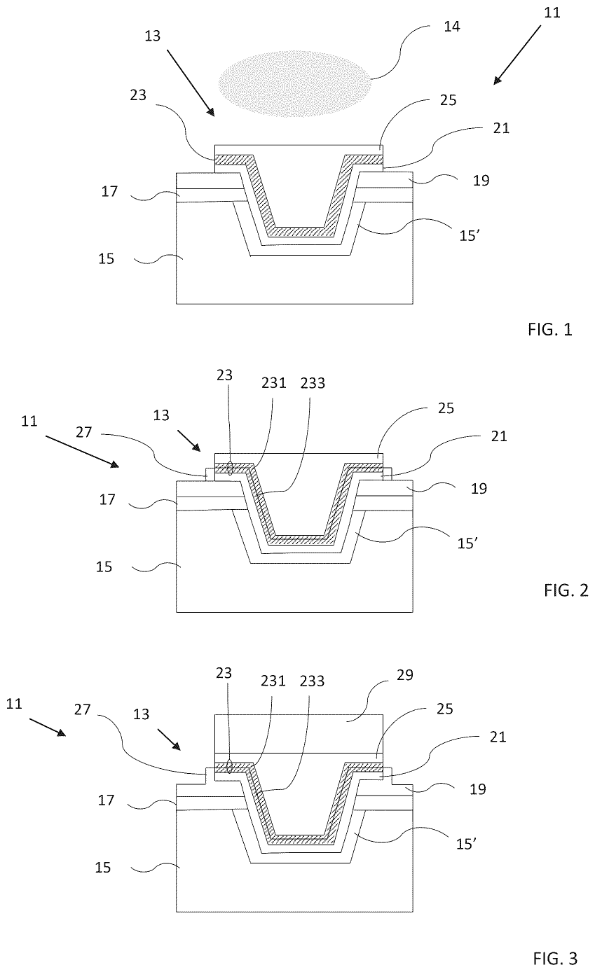

FIG. 1 is a schematic, partial cross-sectional view of an example electronic chip 11 with UBM-type metallization 13, also referred to as metallic pad.

The electronic chip 11 for example comprises a photodiode, for example an infrared photodiode. The chip is, for example, intended to be associated with a cooling system, such as a cryogenic cooling system, aimed at limiting the parasitic thermal noise measured by the photodiode.

In order to be assembled and electrically connected to another electronic device, the chip 11 can receive, on, and in contact with, the top face of the metal pad 13, a soldering material 14, for example in the form of a connecting ball.

The soldering material 14 is, for example, indium (In), or an indium-based alloy. Indium-based soldering materials indeed have good electrical conductivity and mechanical strength over a wide temperature range, particularly at cryogenic temperatures.

The electronic chip 11 includes a semiconductor substrate 15, on which the metal pad 13 is formed.

By way of example, the bottom face of the metal pad 13 contacts the top face of substrate 15.

For example, the substrate 15 is made of a semiconductor material, such as a cadmium (Cd), mercury (Hg), and telluride (Te) alloy known as CMT. For example, the substrate 15 is doped, for example of a first type of conductivity, such as N-type, for example doped with indium atoms. By way of example, at the interface with the metal pad 13, the substrate 15 is doped of a second type of conductivity, e.g. of P-type, for example doped with arsenic, or antimony atoms, so that a region 15′ is formed.

As an example, the substrate 15 is overlaid by at least one passivation layer. For example, the substrate 15 is covered by two passivation layers 17 and 19. In the example shown, a lower part of the metal pad 13 is arranged into a cavity passing vertically through the passivation layers 17 and 19, and opening onto the substrate 15. More specifically, in this example, the cavity extends through part of the thickness of the substrate 15. In this way, the metal pad 13 extends partially into the substrate 15. By way of example, the passivation layers 17 and 19 are electrically insulating. Layer 17 is, for example, located on, and in contact with, the substrate 15 and is, for example, made of an undoped semiconductor material, for example a semiconductor material with a bandgap greater than that of the material of the substrate 15, for example tellurium-cadmium (CdTe). Layer 19 is for example located on, and in contact with, the layer 17, and is for example made of a dielectric material such as zinc sulphide (ZnS), silicon oxide (SiOx), and/or silicon nitride (SiN).

The metal pad 13 corresponds in this example to a stack of three layers, a first metal layer 21, an electrically conductive barrier layer 23, and a second metal layer 25. By way of example, the layer 21 is arranged on, and in contact with, the top face of the substrate 15, the layer 23 is arranged on, and in contact with, the top face of the layer 21, and the layer 25 is arranged on, and in contact with, the top face of the layer 23. In this example, the soldering material 14 is intended to be brought into contact with the top face of the layer 25.

The metal layer 21 is for example made of gold (Au) which has the advantage of allowing good ohmic contact with the P-doped region 15′ of the CMT substrate 15.

Layer 25, for example, is also made of gold (Au), which has the advantage of allowing good adhesion of indium-based soldering materials.

The barrier layer 23 is, in this example, adapted to prevent diffusion of indium from the soldering material 14 into the metal pad. Indeed, in practice, indium readily reacts with gold to form a gold-indium intermetallic alloy, which is more voluminous than gold. The function of the barrier layer 23 is to block indium diffusion, and prevent indium migration towards the bottom face of the metal pad 13, and in particular towards the substrate 15. Indeed, indium migration towards the bottom face of the metal pad 13 creates a risk for the mechanical integrity of the metal pad 13 due to the formation of the intermetallic alloy in layer 21. By way of example, the barrier layer 23 comprises a stack of one or more electrically conductive layers, for example a stack of a titanium (Ti) layer and a platinum (Pt) layer, or a stack of a chromium (Cr) layer and a platinum layer.

As an example, when viewed from above, the metal pad 13 has a round or square shape. However, the described embodiments are not limited to this particular case.

In this example, the layers 21, 23, and 25 extend over the top face of the passivation layer 19 in a peripheral part of the metal pad 13.

By way of example, layers 21, 23, and 25 are first successively deposited over the entire top surface of the chip, then etched, for example by means of a single photolithography step, to form the pad 13. As a result, the sidewalls of the layers 21, 23, and 25 of the pad 13 are vertically aligned, as shown in the figure.

A limitation of the structure shown in FIG. 1 is that the sidewalls of the layers 21, 23, and 25 are exposed. Thus, during assembly, a part of the soldering material 14 is likely to cover the sidewalls of the pad, and, in particular, to come into contact with the sidewalls of the lower gold layer 21. In this case, the indium in the soldering material may cause the gold-indium alloy to form in all or some part of the layer 21, leading to chip degradation.

One way of overcoming this limitation is to implement two separate photolithography steps to produce the metal pad 13. As an example, the lower gold layer 21 is first deposited and then etched by means of a first photolithography step. Layers 23 and 25 are then deposited and etched by means of a second photolithography step. In the second photolithography step, the masked part has a larger surface area than the part masked in the first step, so that the barrier layer 23 and the upper gold layer 25 cover the sidewalls of the lower gold layer 21, preventing any risk of contact between the lower gold layer 21 and the soldering material 14. In addition to the cost of double photolithography, precise alignment of the two photolithographies is required. The reduction in chip sizes makes this alignment problematic.

FIG. 2 is a partial, schematic cross-sectional view of an electronic chip with UBM-type metallization or metal contact pad 13 according to one embodiment.

The metal contact pad 13 shown in FIG. 2 is similar to the metal contact pad 13 shown in FIG. 1 except that, in the example shown in FIG. 2, an electrically insulating barrier layer 27 is arranged on, and in contact with, the sidewall of the lower gold layer 21 around the entire periphery of the metal pad 13.

The insulating barrier 27 is arranged over the entire height of the sidewall of the layer 21, so that the sidewall of the layer 21 is completely covered by the insulating barrier 27. By way of example, the insulating barrier 27 has a height greater than or equal to the thickness of the layer 21, i.e. the height of the sidewall of the layer 21.

By way of example, the insulating barrier 27 has a height greater than the thickness of the layer 21, it then covers all or part of the height of the sidewalls of the layer 23 and of the layer 25.

By way of example, the barrier layer 23 comprises a stack of two layers 231 and 233 of different electrically conductive materials. As an example, the layer 231 is located on, and in contact with, the top face of the metal layer 21, and the layer 233 is located on, and in contact with, the top face of the layer 231. The layer 25, for example, is located on, and in contact with, the top face of the layer 233. The layer 231 is for example made of titanium (Ti), or chromium (Cr). The layer 233 is for example made of platinum (Pt). More generally, the barrier layer 23 may have any other structure or composition suitable for blocking indium diffusion, and forming the gold-indium alloy.

An advantage of the chip shown in FIG. 2 is that the insulating barrier 27 prevents any risk of contact between the soldering material 14 and the sidewalls of the lower gold layer 21.

The insulating barrier 27 can be formed by different methods and thus have different shapes. Example embodiments of the insulating barrier 27 are described in more detail below.

FIG. 3 is a cross-sectional view illustrating in greater detail an example electronic chip of the type described in relation to FIG. 2.

More specifically, in the example shown in FIG. 3, the insulating barrier 27 corresponds to a layer of the same material as the passivation layer 19, formed by redepositing the material of the passivation layer 19 during an etching step.

After depositing layers 17 and 19 on the substrate 15, forming the opening intended to accommodate the metal pad 13, and depositing layers 21, 23, and 25 in the opening and on the top face of layer 19, a step of locally removing by photolithography and etching the layers 21, 23, and 25 is implemented to form the pad 13. In this example, the layers 21, 23, and 25 are removed by means of a single photolithography step. To do this, a resin layer 29 is formed whole wafer on the top face of layer 25, then locally exposed to UV light so that it can be kept opposite the pad 13 to be formed, and removed all around the pad 13. The resulting structure is then etched so that the parts of the layers 21, 23, and 25 not protected by the resin 29 are removed. As a result, the sidewalls of the layers 21, 23, and 25 of the pad are vertically aligned, as shown in the figure.

In this example, the etching is continued after the layers 21, 23, and 25 have been completely removed from outside the opposite side of resin 29, so that a part of the thickness of the layer 19 is etched. This continued etching results in redepositing the material of the layer 19, e.g. ZnS, on, and in contact with, the sidewalls of the pad 13, and in particular on the sidewalls of the lower gold layer 21. By way of example, the etching performed in this step is ion etching.

The width of the insulating barrier 27 and its height are dictated, for example, by the topology of the metal pad 13, the etching angle, and the etching thickness of the layer 19. The etching angle is, for example, 0°with respect to the normal to the top face of the substrate.

By way of example, for a topology (cumulative thickness of the layers 21, 23, 25, and 29 above the top face of the passivation layer 19) of the order of 1.5 μm, an etching angle of the order of 0°, and an etching thickness of the layer 19 of the order of 300 nm, an insulating barrier 27 of the order of 25 nm thickness is obtained on the sidewalls of the layer 21, and on at least a lower part of the sidewalls of the barrier layer 23.

An advantage of the embodiment shown in FIG. 3 is that the metal pad 13 can be formed by means of a single photolithography step. Furthermore, the insulating barrier 27 is formed on the sidewalls of the metal pad 13 without the need for an additional step in the method for manufacturing electronic chips.

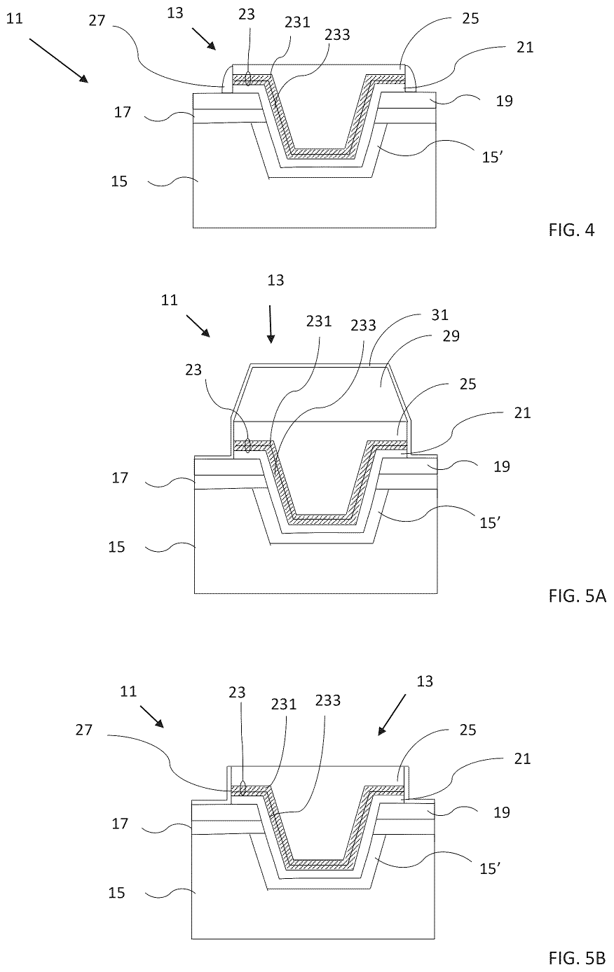

FIG. 4 is a cross-sectional view illustrating in more detail another example embodiment of an electronic chip of the type described in relation to FIG. 2.

In the example shown in FIG. 4, the insulating barrier 27 corresponds to a spacer located on the sidewalls of the layer 21, the spacer being formed by unidirectional etching of an insulating material deposited after the formation of the pad 13.

The metal pad 13 is, for example, produced by photolithography and etching as described above in relation to FIG. 3. In the example shown in FIG. 4, the etching is not extended into the layer 19.

In this example, after the masking resin 29 has been removed, a layer of insulating material, e.g. dielectric material such as zinc sulphide, or silicon dioxide, is deposited whole wafer. In particular, the insulating material covers the top face and sidewalls of the metal pad 13, as well as the top face of the passivation layer 19. By way of example, the insulating material is deposited by a conformal deposition method. By way of example, the layer of insulating material has a thickness of between 10 nm and 150 nm, for example of the order of 50 nm.

The layer of insulating material is then etched by a vertical anisotropic etching method, for example by unidirectional ion etching at an angle of zero with respect to the normal of the top face of the structure, until the top face of the metal pad 13, and the top face of the passivation layer 19 around the pad 13 are exposed. However, the insulating material is preserved on the sidewalls of the metal pad 13, forming the insulating barrier 27.

FIG. 5A and FIG. 5B are cross-sectional views illustrating steps in another example method for producing an electronic chip of the type described in relation to FIG. 2.

In the example shown in FIGS. 5A and 5B, the insulating barrier 27 corresponds to a layer located on the sidewalls of the layer 21, and localized by means of a sacrificial resin layer.

The metal pad 13 is, for example, produced by photolithography and etching as described above in relation to FIG. 3. In the example shown in FIGS. 5A and 5B, the etching is not extended into the layer 19.

In this example, the masking resin 29 is kept on the top surface of the metal pad 13 after etching. A layer 31 of insulating material is then deposited, for example in a conformal manner, e.g. whole wafer. In this example, layer 31 extends over, and in contact with, the top face and sidewalls of the resin layer 29, the sidewalls of the metal pad 13, and the top face of the layer 19. FIG. 5A illustrates the structure obtained after this deposition step. By way of example, the layer 31 has a thickness of between 10 nm and 100 nm, for example of the order of 50 nm.

As an example, the layer 31 is made of a dielectric material, such as zinc sulphide or silicon dioxide.

The step of depositing the layer 31 is followed by a so-called lift-off step. During this step, the resin layer 29 is removed with the parts of the layer 31 covering it, and only the parts of the layer 31 located on the sidewalls of the UBM 13, and on the top face of layer 19 are kept so that the insulating barrier 27 is formed. By way of example, this lift-off step is carried out by washing the structure with a solvent. FIG. 5B illustrates the structure obtained after this step.

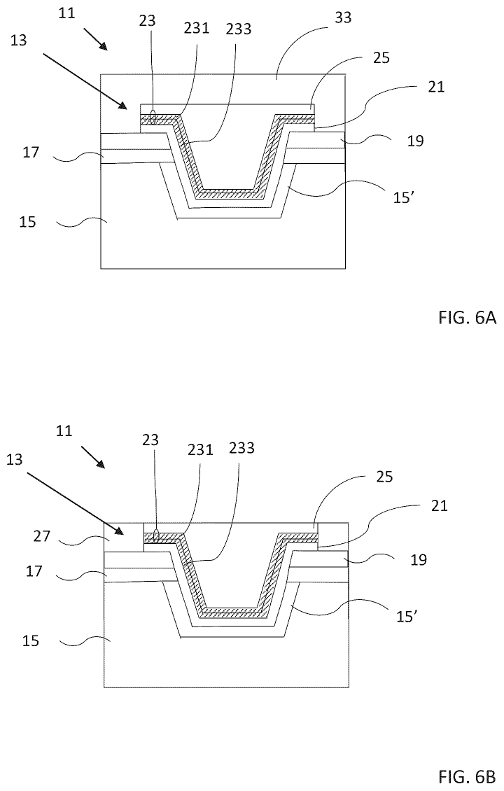

FIG. 6A and FIG. 6B are cross-sectional views illustrating steps in a further example method for producing an electronic chip of the type described in relation to FIG. 2.

In this example, the insulating barrier 27 corresponds to a layer flushing with the top face of the layer 21, and filling the free space around the metal pad 13.

The metal pad 13 is, for example, performed by photolithography and etching as described above in relation to FIG. 3. In the example shown in FIGS. 6A and 6B, the etching is not extended into the layer 19.

After removal of the masking resin 29, the insulating barrier 27 is in this example formed by deposition of an insulating layer 33, whole wafer, i.e. on, and in contact with, the top face of the layer 19, the top face of the UBM 13, and the sidewalls of the UBM 13. The insulating layer 33 is made, for example, of a dielectric material, such as zinc sulphide or silicon dioxide.

In this example, the layer 33 is formed with a thickness greater than the thickness of the metal pad 13, i.e. of the cumulative thickness of the layer 21, of the layer 23, and of the layer 25, above the passivation layer 19. In this way, the UBM 13 is completely covered by the layer 33, as shown in FIG. 6A. By way of example, the layer 33 has a thickness greater than 600 nm. For example, layer 33 has a substantially flat top surface.

Following the step of depositing the layer 33, the structure is planarized or thinned, for example by chemical-mechanical planarization. Planarization is stopped, for example, when the top face of the metal pad 13 is exposed. At the end of this step, the top face of the metal pad 13 is flush with the top face of the layer 33 forming the insulating barrier 27, as illustrated in FIG. 6B.

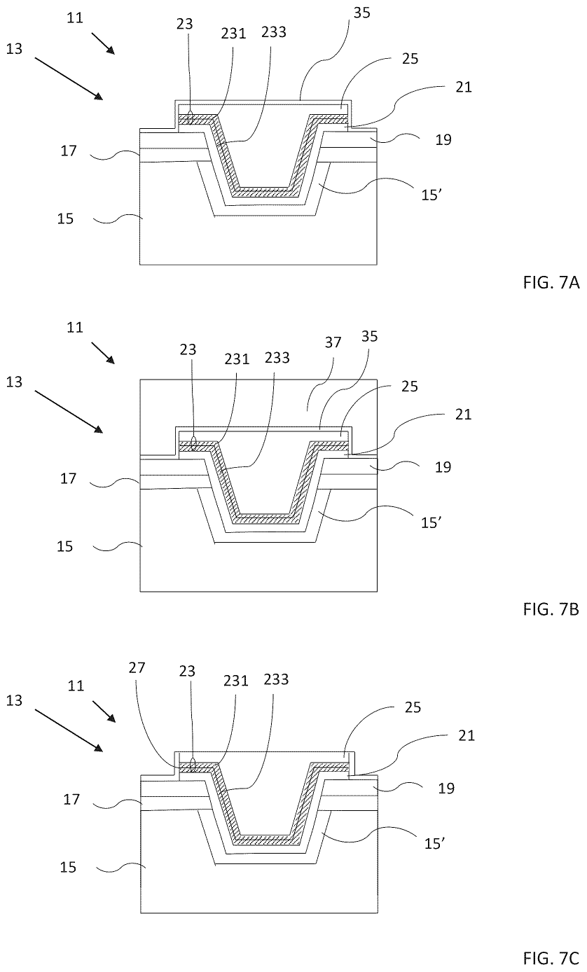

FIG. 7A, FIG. 7B, and FIG. 7C are cross-sectional views illustrating steps in a further example method for producing an electronic chip of the type described in relation to FIG. 2.

The metal pad 13 is, for example, performed by photolithography and etching as described above in relation to FIG. 3. In the example shown in FIGS. 7A, 7B, and 7C, the etching is not extended into the layer 19.

In this example, after removal of the masking resin layer 29, an insulating layer 35 is deposited, for example in a conformal manner, e.g. whole wafer. In particular, the layer 35 is deposited on, and in contact with, the top face of the layer 19, and on, and in contact with, the top face and sidewalls of the metal pad 13, so that the structure illustrated in FIG. 7A is formed. As an example, the insulating layer 35 is made of a dielectric material, such as zinc sulphide or silicon dioxide. By way of example, the layer 35 has a thickness of between 50 and 500 nm, for example of the order of 200 nm.

Following this step of depositing the layer 35, a sacrificial layer or planarization layer 37 is deposited over the entire surface of the layer 35 and, for example, in contact with the latter. The sacrificial layer 37 is, for example, a resin layer. Layer 37 is, for example, deposited with a thickness greater than the thickness of the UBM 13, so that the UBM is completely covered by the layer 37 and thus forms the structure illustrated in FIG. 7B. Layer 37 is deposited, for example, by centrifuging. By way of example, at the end of this step, the top face of the layer 37 is flat.

Following depositing the layers 35 and 37, a step of etching is implemented on the side of the top face of the structure, e.g. plasma etching. By way of example, the etching has an etching speed for the layer 37 greater than that for the layer 35. During this step, the layer 37 is thinned from its top face until the top face of the portion of the layer 35 coating the top face of the metal pad 13 is exposed. By way of example, at the end of this step, the metal pad 13 is flush with the top face of the resin layer 37. Thus, the parts of the layer 35 coating the top face of the layer 19 and the sidewalls of the pad 13 remain covered by the resin layer 37.

A second etching, such as an ion etching, can then be implemented to remove the part of the layer 35 located on the top face of the metal pad 13. By way of example, the second etching is selective and stops as soon as the top surface of the layer 25 is exposed.

Further chemical etching, such as wet etching, can then be implemented to remove the sacrificial resin 37 around the metal pad 13 so that the structure shown in FIG. 7C is formed.

At this stage, the dielectric layer 35 coats at least a lower part of the sidewalls of the metal pad 13, forming the barrier layer 27.

One advantage of the methods described in relation to FIGS. 3, 4, 5A, 5B, 6A, 6B, 7A, 7B, 7C is that they allow the metal pad 13 and insulating barrier 27 to be formed in a single photolithography step.

Various embodiments and variants have been described. Those skilled in the art will understand that certain features of these embodiments can be combined and other variants will readily occur to those skilled in the art. In particular, the embodiments described are not limited to the above-mentioned examples of dimensions and materials.

In particular, although a particular example of application to gold-based metal pads intended to receive an indium-based soldering material has been described above, the described embodiments are not limited to this particular case. More generally, the person skilled in the art will know how to adapt the described embodiments to any UBM-type metal stack including at least one lower metal layer, one barrier layer, and one upper metal layer intended to receive a soldering material, wherein it is desirable to avoid contact between the soldering material and the lower metal layer.

In addition, although the embodiments have been described for chips including infrared photodiodes, they can be readily adapted to other chip types.

Finally, the practical implementation of the embodiments and variants described herein is within the capabilities of those skilled in the art based on the functional description provided hereinabove.

1. An electronic chip including a semiconductor substrate and, on the side of one face of the substrate, a metal pad intended to receive a soldering material, the pad including, in order from said face of the substrate, a first metal layer on, and in direct contact with, said face of the substrate, an electrically conductive barrier layer on, and in contact with, said first metal layer, and a second metal layer on, and in contact with, said electrically conductive barrier layer, wherein the sidewalls of the first metal layer, of the electrically conductive barrier layer, and of the second metal layer are vertically aligned, and wherein an electrically insulating barrier layer is disposed on, and in contact with, the vertical sidewall of the first metal layer around the entire periphery of the metal pad.

2. The chip of claim 1, wherein the electrically insulating barrier layer is arranged on, and in contact with, at least part of the sidewall of the electrically conductive barrier layer.

3. The chip according to claim 1, wherein the soldering material comprises indium.

4. The chip according to claim 1, wherein the first and second metal layers are made of gold.

5. The chip according to claim 1, wherein the electrically insulating barrier layer is made of zinc sulphide or silicon dioxide.

6. The chip according to claim 1, wherein the substrate is made of a cadmium-mercury-telluride-based alloy.
